(19) United States
(12) Patent Application Publication
(10) Pub. No.: US 2013/0146118 A1
(43) Pub. Date: Jun. 13, 2013

(54) Silicone Junction Box and Assemblies

(71) Applicant: Dow Corning Corporation, Midland, MI (US)

(72) Inventors: Elizabeth Kelley, Hope, MI (US); David McDougall, San Jose, CA (US); Ann Norris, Blacksburg, VA (US)

(73) Assignee: Dow Corning Corporation, Midland, MI (US)

(21) Appl. No.: 13/675,223

(22) Filed: Nov. 13, 2012

Related U.S. Application Data
(60) Provisional application No. 61/569,401, filed on Dec. 12, 2011.

(51) Int. Cl. H05K 5/02; H01L 31/042

(52) U.S. Cl. CPC H05K 5/02; H01L 31/042
USPC 136/244; 174/541

(57) ABSTRACT

This invention comprises a silicone junction box comprising a silicone base member comprising a silicone composition for housing an electrical connection and a cover member in sealing operative contact with the silicone base member; and a photovoltaic panel assembly and photovoltaic system comprising the silicone junction box.

### STATEMENT REGARDING FEDERALLY SPONSORED RESEARCH

Not applicable.

This invention comprises a silicone junction box and related assemblies.

A junction box is a housing or enclosure within which electric circuits are connected. A photovoltaic use-type junction box is a type of junction box that is constructed or adapted for use with a photovoltaic cell panel or module and associated environmental conditions. Different configurations of non-silicone photovoltaic use-type junction boxes are mentioned in, for example, U.S. Pat. No. 7,833,033 B2; U.S. Pat. No. 7,134,883 B2; U.S. Pat. No. 7,097,516 B2; U.S. Pat. No. 6,582,249 B1; US 2011/0168228 A1; US 2011/0147076 A1; and US 2005/0161080 A1.

### BRIEF SUMMARY OF THE INVENTION

This invention comprises a silicone junction box and assemblies comprising same. The silicone junction box may be adapted for use with any electrical device in need of a housing or enclosure within which to connect electric circuits.

First, this invention is a silicone junction box comprising a silicone base member comprising a silicone composition for housing an electrical connection and a cover member in sealing operative contact with the silicone base member.

Second, this invention is a photovoltaic panel assembly comprising components (a) to (c): (a) a subassembly of electrically connected photovoltaic cells; (b) a photovoltaic use-type silicone junction box comprising a silicone base member comprising a silicone composition for housing an electrical connection and a cover member in sealing operative contact with the silicone base member; and (c) an electrical connector disposed within the silicone junction box and in electrical connection to the subassembly.

Third, this invention is a photovoltaic system comprising components (a) to (d): (a) a subassembly of electrically connected photovoltaic cells; (b) a photovoltaic use-type silicone junction box comprising a silicone base member comprising a silicone composition for housing an electrical connection and a cover member in sealing operative contact with the silicone base member; (c) an electrical connector disposed within the silicone junction box and in electrical connection to the subassembly; and (d) an electric cable extending into the silicone junction box and in sequential electrical connection to the electrical connector and subassembly.

The silicone junction box can house electrical connections such as fuses and wiring interconnects used in, e.g., lighting, photovoltaic, appliance, and electrical outlet applications.

### BRIEF DESCRIPTION OF THE DRAWINGS

Some invention embodiments are described in relation to the accompanying drawings. FIG. 1 is a perspective view of an embodiment of the silicone junction box with a cover member in an open position.

FIG. 2 is a perspective view of an aspect of the silicone base member and further comprising electrical connectors.

FIG. 3 is a perspective view of the embodiment of FIG. 1 and further comprising a printed circuit board.

FIG. 4 is a cross-sectional view through the printed circuit board and showing contact elements.

FIG. 5 is a perspective view of an embodiment of the printed circuit board.

FIG. 6 is a perspective view of a conductor rail.

FIG. 7 is a perspective view showing an alternate embodiment wherein a printed circuit board is fastened to the cover member.

FIG. 8 is a cross-sectional view through the embodiment of the silicone junction box.

### DETAILED DESCRIPTION OF THE INVENTION

The Brief Summary and Abstract are incorporated here by reference.

The inventor(s) discovered problems with prior art junction boxes made of an organic polymer (e.g., poly(vinyl chloride)) or metal (steel) material. These materials disadvantageously lack flexibility and adhesiveness to silicone pottants. Rigid prior art junction boxes are susceptible to cracking or permanently deforming, which may directly and fatally expose the electrical connections disposed therein to abusive environments (e.g., dust, heat, cold, light, physical impact, or vibration). Interior surfaces of prior art junction boxes first need to be primed or activated before they may adequately adhere to and maintain sealing connection with the silicone pottant.

This invention solves some of the problems with prior art junction boxes. A solution comprises an alternative junction box comprising, alternatively consisting essentially of, alternatively consisting of, the silicone composition for housing an electrical connection. In addition to its aforementioned suitability, the silicone junction box has a silicone exterior surface that advantageously has sufficient adhesion to a silicone adhesive without priming or activating it beforehand; a silicone interior surface that advantageously has sufficient adhesion to a silicone pottant without priming or activating it beforehand; or both. Further, the silicone composition may be a cured liquid silicone rubber (LSR), which has the sufficient adhesion to silicone pottants and provides a silicone junction box that is also flexible. The flexible silicone junction box advantageously may be placed in and adapt to confining locations that are unsuitable for hosting rigid non-invention junction boxes and/or may be used in abusive environments such as those found in military, construction or mining applications. Certain aspects of this invention may independently solve additional problems and/or have other advantages.

The electrical connection(s) and connector(s) respectively may be any type that may be housed in a silicone junction box. For example, the electrical connector(s) may be (a) cable coupler(s), (b) capacitor(s), (c) conducting adhesive, (d) conductor rail(s), (e) fuse(s), (f) ground clip(s), (g) integrated circuit(s), (h) multicontact connector(s), (i) pin contact(s), (j) printed circuit board(s), (k) solder, (l) terminal(s), (m) terminal pin(s), (n) T-branch connector(s), (o) trace(s), (p) Type 4 connector(s), (q) wire connector(s), or (r) any combination at least two thereof. The silicone junction box may be a photovoltaic use-type silicone junction box and the electrical connector(s) may be photovoltaic use-type electrical connector(s) such as at least one of (a), (c), (d), (f), (h), (i), (j), (k), (l), (m), (n), (o), (p), (q), or (s) any combination of at least two thereof. The photovoltaic use-type silicone junction box and electrical connector(s) are designed, constructed or adapted for use with photovoltaic cell module(s) or panel(s) and associated environmental conditions. The electrical connector(s) may be operatively attached to the silicone base member, the cover member, or a combination thereof. The silicone junction box may further comprise additional components such as rail covers, fasteners such as spring clips, and supporting members such as component holders.

The cover member may be any suitable junction box material, e.g., stainless steel, coated metal, organic polymer (e.g., poly(vinyl chloride) or polypropylene), or the silicone composition. The silicone cover member may comprise a different silicone composition, alternatively the same silicone composition as the silicone composition of the silicone base member.

The silicone composition independently may comprise any organosiloxane material that is functionally suitable for housing an electrical connection under conditions expected to be encountered by the silicone junction box. Those conditions may include, for example, indoor or outdoor use, low voltage or high voltage applications, high humidity or low humidity conditions, prolonged or repeated exposure to ultraviolet (UV) light or infrequent exposure to UV light, ambient atmosphere or non-ambient atmosphere (e.g., inert gas atmosphere, or flammable solvent vapor atmosphere), or a combination of any two or more thereof. Such an organosiloxane material may be characterizable as having an ASTM International test value, Underwriters Laboratories Inc. (UL) rating or classification, International Electrotechnical Commission (IEC) rating or classification, International Organization for Standardization (ISO), or a combination of any two or more thereof, suitable for junction boxes. For example, the silicone junction box may be a photovoltaic use-type silicone junction box, and the silicone base member, or silicone base member and cover member, thereof, and thus the silicone composition from which the silicone base member, or silicone base member and cover member are prepared or formed, may meet minimum evaluation standards for general photovoltaic use-type junction boxes. Such evaluation standards for photovoltaic use-type junction boxes may include UL 1703 (Standard for Safety of Flat-Plate Photovoltaic Modules and Panels) and UL 746C (Standard for Safety of Polymeric Materials—Use in Electrical Equipment Evaluations). For example using UL 1703 and UL 746C, the photovoltaic use-type junction box may have an Outdoor use rating of f2 or better (ultraviolet light and water resistance), e.g., f1 or better; a Flammability rating of 5VA or better; a Hot Wire Ignition (HWI) rating of ≦4; a High-current Arc Ignition (HAI) rating of ≦3; a Comparative tracking index rating of ≦2; and a Relative Thermal Index (RTI) rating of ≧90 degrees Celsius (° C.). Alternatively, the RTI rating may be ≧120° C., alternatively ≧125° C. when tested according to test method UL 746B. Further using UL 1703, the photovoltaic use-type junction box may pass the following tests: the leakage current test, dielectric voltage withstand test, water spray test, impact test (UL 1703 section 30), strain relief test, and temperature test. Alternatively or additionally, the silicone base member, or silicone base and cover members, of the photovoltaic use-type silicone junction box may have a dielectric strength of at least 350 Volts per mil (V/mil; ≧140,000 Volts per centimeter (V/cm)) when tested according to ASTM D-149-09 (Standard Test Method for Dielectric Breakdown Voltage and Dielectric Strength of Solid Electrical Insulating Materials at Commercial Power Frequencies); a flammability classification of V-0 or better when tested according to IEC 60695-11-10, edition 1.1 (Fire hazard testing—Part 11-10: Test flames—50 W horizontal and vertical flame test methods)); and a flammability rating of V-0 or better when tested according to IEC 60695-11-20, edition 1.1 (Fire hazard testing—Part 11-20: Test flames—500 W flame test methods). Alternatively, flammability may be classified according to UL 94 (Standard for Tests for Flammability of Plastic Materials for Parts in Devices and Appliances), which may be harmonized with the IEC 60695-11-10 and -20 tests and with ISO 9772:2001 (Cellular plastics—Determination of horizontal burning characteristics of small specimens subjected to a small flame) and ISO 9773:1998 (Plastics—Determination of burning behavior of thin flexible vertical specimens in contact with a small-flame ignition source).

The silicone composition may be in any organosiloxane material that can be molded, shaped, or otherwise manufactured in a suitable configuration for junction boxes. The organosiloxane material may be oligomeric, alternatively polymeric. The polymeric organosiloxane material (polyorganosiloxane) may be unbranched, alternatively branched. The silicone composition may be in the form of a silicone resin, gel, or gum; a high consistency rubber (HCR) silicone; or a liquid silicone rubber (LSR) that has been cured. The silicone composition may be a siloxane, silazane, silylene, silene, silanol, a polymer thereof, or any combination thereof. Alternatively, the silicone composition may be used in combination with any one of an organosilazane, organosilene, organosilanol, a polymer thereof, or any combination thereof. The silicone composition may be partially or completely cured. The curing may be achieved by any suitable mechanism such as by a free radical reaction, hydrosilylation reaction, condensation or addition reaction, heat curing, peroxide curing, UV curing, or any combination thereof.

Typically, the silicone composition is an LSR. Typically the LSR, before curing, is hydrosilylation curable; and afterward is at least partially hydrosilylation-cured. The silicone composition, however, is not limited to hydrosilylation curable/cured silicone chemistry. Before the at least partial curing, the hydrosilylation-curable LSR typically comprises ingredients (A) to (C): (A) at least one diorganosilicon compound having an average of at least two unsaturated carbon-carbon bonds per molecule; (B) an organohydrogensilicon compound having an average of at least three Si—H moieties per molecule; and (C) a catalytically effective amount of a hydrosilylation catalyst. During curing, ingredients (A) and (B) react together via hydrosilylation to give the at least partially hydrosilylation cured LSR. The reaction may give substantial curing; alternatively complete curing. The hydrosilylation cured LSR may be substantially cured, alternatively completely cured. Substantially cured means a degree of curing that is at least 90 mole %, alternatively at least 95 mole %, alternatively at least 98 mole % cured based on the limiting ingredient. The degree of curing may be determined by proton, carbon-13, or ²⁹Si nuclear magnetic resonance (NMR). Each diorganosilicon compound and organohydrogensilicon compound independently may be the same (i.e., have both Si—H and unsaturated carbon-carbon bonds in same molecule), alternatively different. When ingredients (A) and (B) are the same compound, the curing comprises intermolecular hydrosilylations and may also comprise intramolecular hydrosilylations. When ingredients (A) and (B) are different compounds, the curing comprises intermolecular hydrosilylations.

Ingredient (A), the at least one diorganosilicon compound, is hydrosilylation-curable and may include a single diorganosilicon compound, or a plurality of different diorganosilicon compounds. As suggested in the foregoing paragraph, each diorganosilicon compound may contain, alternatively lack a Si—H moiety. Each diorganosilicon compound independently may have an average of at least 2, alternatively >2, alternatively ≧3, alternatively ≧5, alternatively ≧10, alternatively ≧20 unsaturated carbon-carbon bonds per molecule. Each unsaturated carbon-carbon bond independently is C═C or C≡C. Typically at least one of the unsaturated carbon-carbon bonds is C═C, alternatively all of the unsaturated carbon-carbon bonds are C═C, alternatively at least one of the unsaturated carbon-carbon bonds is C≡C, alternatively all are C≡C, alternatively the unsaturated carbon-carbon bonds are a combination of C═C and C≡C. The diorganosilicon compound may be an alkynyl siloxane or alkenyl siloxane wherein there are at least two alkynyl or alkenyl groups, respectively, and each of the alkynyl or alkenyl groups may be pending from a carbon, oxygen, or silicon atom. Each alkenyl group independently may have one or more C═C bonds. Each alkenyl may have one C═C and be a (C₂-C₆)alkenyl, alternatively (C₂-C₄)alkenyl (e.g., vinyl or allyl). The C═C bond in the alkenyl may be internal as in 5-hexen-1-yl or terminal alkenyl as in H₂C═C(H)—(C₀-C₆)alkylene (H₂C═C(H)—(C₀)alkylene is vinyl). The alkynyl and alkenyl groups independently may be located at any interval and/or location in the diorganosilicon compound such as terminal, pendant, or both terminal and pendant (internal) positions. The diorganosilicon compound(s) may be a mixture or blend of at least two different diorganosilicon compounds, so long as ingredient (A) has the average of at least two unsaturated carbon-carbon bonds per molecule. The diorganosilicon compound may be a cyclic diorganosiloxane monomer or a polydiorganosiloxane.

The polydiorganosiloxane may be straight or branched, uncrosslinked or crosslinked and comprise at least two D units. Any polydiorganosiloxane may further comprise additional D units. Any polydiorganosiloxane may further comprise at least one M, T, or Q unit in any covalent combination; alternatively at least one M unit; alternatively at least one T unit; alternatively at least one Q unit; alternatively any covalent combination of at least one M unit and at least one T unit. The polydiorganosiloxane with the covalent combination may be a DT, MT, MDM, MDT, DTQ, MTQ, MDTQ, DQ, MQ, DTQ, or MDQ polydiorganosiloxane. Ingredient (A) may be a mixture or blend of polydiorganosiloxanes, e.g., a mixture of MDM and DT molecules. Known symbols M, D, T, and Q, represent the different functionality of structural units that may be present in a siloxane (i.e., silicone), which comprises siloxane units joined by covalent bonds. The monofunctional (M) unit represents R₃SiO_{1/2}; the difunctional (D) unit represents R₂SiO_{2/2}; the trifunctional (T) unit represents RSiO_{3/2} and results in the formation of branched linear siloxanes; and the tetrafunctional (Q) unit represents SiO_{4/2} and results in the formation of crosslinked and resinous compositions. The reactive group-functional siloxane may be R¹SiO_{3/2} units (i.e., T units) and/or SiO_{4/2} units (i.e., Q units) in covalent combination with R¹R⁴₂SiO_{1/2} units (i.e., M units) and/or R⁴₂SiO_{2/2} units (i.e., D units). Each “R” group, e.g., R, R¹ and R⁴ independently is hydrocarbyl, heterohydrocarbyl, or organoheteryl, which are collectively referred to herein as organogroups. Each hydrocarbyl, heterohydrocarbyl, and organoheteryl independently may have from 1 to 20, alternatively from 1 to 10, alternatively from 1 to 8, alternatively from 1 to 6 carbon atoms. Each heterohydrocarbyl and organoheteryl independently comprises carbon, hydrogen and at least one heteroatom that independently may be halo, N, O, S, or P; alternatively S; alternatively P; alternatively halo, N, or O; alternatively halo; alternatively halo; alternatively O; alternatively N. Each heterohydrocarbyl and organoheteryl independently may have up to 4, alternatively from 1 to 3, alternatively 1 or 2, alternatively 3, alternatively 2, alternatively 1 heteroatom(s). Each heterohydrocarbyl independently may be halohydrocarbyl (e.g., fluoromethyl, trifluoromethyl, trifluorovinyl, or chlorovinyl), alternatively aminohydrocarbyl (e.g., H₂N-hydrocarbyl) or alkylaminohydrocarbyl, alternatively dialkylaminohydrocarbyl (e.g., 3-dimethylaminopropyl), alternatively hydroxyhydrocarbyl, alternatively alkoxyhydrocarbyl (e.g., methoxyphenyl). Each organoheteryl independently may be hydrocarbyl-N(H)—, (hydrocarbyl)₂N—, hydrocarbyl-P(H)—, (hydrocarbyl)₂P—, hydrocarbyl-O—, hydrocarbyl-S—, hydrocarbyl-S(O)—, or hydrocarbyl-S(O)₂—. Each hydrocarbyl independently may be (C₁-C₈)hydrocarbyl, alternatively (C₁-C₆)hydrocarbyl, alternatively (C₁-C₃)hydrocarbyl, alternatively (C₁-C₂)hydrocarbyl. Each (C₁-C₈)hydrocarbyl independently may be (C₇-C₈)hydrocarbyl, alternatively (C₁-C₆)hydrocarbyl. Each (C₇-C₈)hydrocarbyl may be a heptyl, alternatively an octyl, alternatively benzyl, alternatively tolyl, alternatively xylyl. Each (C₁-C₆)hydrocarbyl independently may be (C₁-C₆)alkyl, (C₂-C₆)alkenyl, (C₂-C₆)alkynyl, (C₃-C₆)cycloalkyl, or phenyl. Each (C₁-C₆)alkyl independently may be methyl, ethyl, propyl, butyl, or pentyl; alternatively methyl or ethyl; alternatively methyl; alternatively ethyl. Each halo independently may be bromo, fluoro or chloro; alternatively bromo; alternatively fluoro; alternatively chloro. Each R, R¹- and R⁴ independently may be hydrocarbyl; alternatively halohydrocarbyl; alternatively hydrocarbyl and at least one heterohydrocarbyl; alternatively hydrocarbyl and at least one organoheteryl. There may be an average of at least 1 “R” per molecule having an alkenyl or alkynyl group capable of undergoing hydrosilylation. For example, there may be an average of at most 4, alternatively at least 1, alternatively >1, alternatively at least 2, alternatively 3, alternatively from 1 to 4, alternatively from 1 to 3 alkenyl or alkynyl group per diorganosilicon molecule each independently capable of undergoing hydrosilylation. Examples of suitable alkenyl are vinyl, fluorovinyl, trifluorovinyl, allyl, 4-buten-1-yl, and 1-buten-4-yl. Examples of suitable alkynyl are acetylenyl, propyn-3-yl, and 1-butyn-4-yl.

The polydiorganosiloxane may be a polydialkylsiloxane, e.g., an alkyldialkenylsiloxy-terminated polydialkylsiloxane or a dialkylalkenylsiloxy-terminated polydialkylsiloxane, e.g., a dialkylvinylsiloxy-terminated polydialkylsiloxane. Examples of the dialkylvinylsiloxy-terminated polydialkylsiloxane are dimethylvinylsiloxy-terminated polydimethylsiloxane; diethylvinylsiloxy-terminated polydimethylsiloxane; methyldivinylsiloxy-terminated polydimethylsiloxane; dimethylvinylsiloxy-terminated polydiethylsiloxane; dimethylvinylsiloxy-terminated poly(methyl,ethyl)siloxane; poly(methyl,(C₇-C₈)hydrocarbyl)siloxane; and combinations thereof. Alternatively, the polydiorganosiloxane may be a hydroxyl-terminated polydiorganosiloxane. The hydroxyl-terminated polydiorganosiloxane may be a hydroxyl-terminated polydialkylsiloxane having pendent alkenyl, alkynl, or alkenyl and alkenyl groups. Examples of the hydroxyl-terminated polydialkylsiloxane are hydroxyl-terminated polydimethylsiloxane having pendent vinyl groups; hydroxyl-terminated polydiethylsiloxane having pendent vinyl groups; hydroxyl-terminated poly(methyl,ethyl)siloxane having pendent vinyl groups; hydroxyl-terminated poly(methyl,(C₇-C₈)hydrocarbyl)siloxane having pendent vinyl groups; and combinations thereof. Terminated means mono (alpha), alternatively bis(both alpha and omega) termination. Alternatively, any one of the foregoing polydialkylsiloxanes may further comprise one or more (e.g., from 1 to 3) internal (alkyl,alkynyl) units, alternatively internal (alkyl,alkenyl) units (e.g., methyl,vinyl or ethyl,vinyl units) or one or more (e.g., from 1 to 3) alkenyl-containing pendent groups, e.g., a dimethylvinylsiloxy-pendent group-containing polydimethylsiloxane. Alternatively, the polydiorganosiloxane may be an alkenyldialkylsilyl end-blocked polydialkylsiloxane; alternatively a vinyldimethylsilyl end-blocked polydimethylsiloxane. Ingredient (A) may be a polydiorganosiloxane comprising methyl and vinyl R groups. Ingredient (A) may be a poly(methyl,vinyl)siloxane (homopolymer); alternatively a hydroxyl-terminated poly(methyl,vinyl)siloxane (homopolymer); alternatively a poly(methyl,vinyl)(dimethyl)siloxane copolymer; alternatively a hydroxyl-terminated poly(methyl,vinyl)(dimethyl)siloxane copolymer; alternatively a mixture of any of at least two thereof. A poly(methyl,vinyl)(dimethyl)siloxane copolymer means a molecule having R¹,R⁴SiO_{2/2} units wherein R¹ is methyl and R⁴ is vinyl and R¹,R¹SiO_{2/2} units wherein each R¹ is methyl.

The cyclic diorganosiloxane monomer may be a cyclic R¹,R⁴ siloxane, wherein R¹ and R⁴ independently are as defined previously. The cyclic R¹,R⁴ siloxane may be a cyclic (C₇-C₈)hydrocarbyl, alkenyl siloxane, cyclic (C₇-C₈)hydrocarbyl, alkynyl siloxane, cyclic alkyl,alkynyl siloxane, or a cyclic alkyl,alkenyl siloxane, wherein (C₇-C₈)hydrocarbyl and alkyl independently are as defined previously. The cyclic alkyl,alkenyl siloxane may be, e.g., a cyclic alkyl,vinyl siloxane, e.g., a cyclic methyl,vinyl siloxane or ethyl,vinyl siloxane.

The diorganosilicon compound may have a number-average molecular weight (Mₙ) of from 500 to 50,000 g/mol, alternatively from 500 to 10,000 g/mol, alternatively 1,000 to 3,000, g/mol, where the Mₙ is determined by gel permeation chromatography employing a low angle laser light scattering detector, or a refractive index detector and silicone resin (MQ) standards. The diorganosilicon compound may have a dynamic viscosity of from 0.01 to 100,000 Pascal-seconds (Pa.$), alternatively from 0.1 to 10,000 Pa·s, alternatively from 1 to 100 Pa·s, when measured at 25° C. according to ASTM D1084-08 (Standard Test Methods for Viscosity of Adhesives). The diorganosilicon compound may have less than 10 wt %, alternatively less than 5 wt %, alternatively less than 2 wt %, of silicon-bonded hydroxy groups, as determined by ²⁹Si—NMR. Alternatively, the diorganosilicon compound may have less than 10 mole percent (mol %), alternatively less than 5 mol %, alternatively less than 2 mol %, of silicon-bonded hydroxy groups, as determined by ²⁹Si-NMR.

Ingredient (B), the organohydrogensilicon compound, has at least one silicon-bonded hydrogen atom per molecule. The organohydrogensilicon compound may be a single organohydrogensilicon compound, or a plurality of different organohydrogensilicon compounds. The organohydrogensilicon compound may have organo groups and an average of at least two, alternatively at least three silicon-bonded hydrogen atoms per molecule. Each organo group independently may be the same as R, R¹, or R⁴ groups as defined before. The organohydrogensilicon compound may be an organohydrogensilane, an organohydrogensiloxane, or a combination thereof. The structure of the organohydrogensilicon compound may be linear, branched, cyclic (e.g., Cyclosilanes and cyclosiloxanes), or resinous. Cyclosilanes and cyclosiloxanes may have from 3 to 12, alternatively from 3 to 10, alternatively 3 or 4 silicon atoms. In acyclic polysilanes and polysiloxanes, the silicon-bonded hydrogen atoms may be located at terminal, pendant, or at both terminal and pendant positions.

The organohydrogensilane may be a monosilane, disilane, trisilane, or polysilane (tetra- or higher silane). Examples of suitable organohydrogensilanes are diphenylsilane, 2-chloroethylsilane, bis[(p-dimethylsilyl)-phenyl]ether, 1,4-dimethyldisilylethane, 1,3,5-tris(dimethylsilyl)benzene, 1,3,5-trimethyl-1,3,5-trisilane, poly(methylsilylene)phenylene, and poly(methylsilylene)methylene.

The organohydrogensiloxane may be a disiloxane, trisiloxane, or polysiloxane (tetra- or higher siloxane). The organohydrogensiloxane may be further defined as an organohydrogenpolysiloxane resin, so long as the resin includes at least one silicon-bonded hydrogen atom per molecule. The organohydrogenpolysiloxane resin may be a copolymer including T units, and/or Q units, in combination with M units, and/or D units, wherein T, Q, M and D are as described above. For example, the organohydrogenpolysiloxane resin can be a DT resin, an MT resin, an MDT resin, a DTQ resin, an MTQ resin, an MDTQ resin, a DQ resin, an MQ resin, a DTQ resin, an MTQ resin, or an MDQ resin. The M, D, T and Q units may be the same as those described previously. Examples of suitable organohydrogensiloxanes are 1,1,3,3-tetramethyldisiloxane, 1,1,3,3-tetraphenyldisiloxane, phenyltris(dimethylsiloxy)silane, 1,3,5-trimethylcyclotrisiloxane, a trimethylsiloxy-terminated poly(methylhydrogensiloxane), a trimethylsiloxy-terminated poly(dimethylsiloxane/methylhydrogensiloxane), a dimethylhydrogensiloxy-terminated poly(methylhydrogensiloxane), and a (H,Me)Si resin. Thus, the organohydrogensilicon compound may be the trimethylsiloxy-terminated poly(dimethylsiloxane/methylhydrogensiloxane).

The organohydrogensilicon compound may have a molecular weight less than 1,000, alternatively less than 750, alternatively less than 500 g/mol. The organohydrogensilicon compound may be a dimethylhydrogensilyl terminated polydimethylsiloxane; alternatively a trialkylsilyl terminated polydialkylsiloxane-alkylhydrogensiloxane co-polymer; alternatively a trimethylsilyl terminated polydimethylsiloxane-methylhydrogensiloxane co polymer; alternatively a mixture of a dialkylhydrogensilyl terminated polydialkylsiloxane and a trialkylsilyl terminated polydialkylsiloxane-alkylhydrogensiloxane co-polymer. The dialkylhydrogensilyl terminated polydialkylsiloxane may be a dimethylhydrogensilyl terminated polydimethylsiloxane. The trialkylsilyl terminated polydialkylsiloxane-alkylhydrogensiloxane co-polymer may be a trimethylsilyl terminated polydimethylsiloxane-methylhydrogensiloxane co-polymer.

Ingredient (C), the hydrosilylation catalyst, is any compound or material useful to accelerate a hydrosilylation reaction between the diorganosilicon compound and the organohydrogensilicon compound. The hydrosilylation catalyst may comprise a metal; a compound containing the metal; or any combination thereof. Each metal independently be platinum, rhodium, ruthenium, palladium, osmium, or iridium, or any combination of at least two thereof. Typically, the metal is platinum, based on its high activity in hydrosilylation reactions. Typically ingredient (C) is the platinum compound. Examples of suitable platinum hydrosilylation catalysts are complexes of chloroplatinic acid and certain vinyl-containing organosiloxanes in U.S. Pat. No. 3,419,593 such as the reaction product of chloroplatinic acid and 1,3-diethenyl-1,1,3,3-tetramethyldisiloxane. The hydrosilylation catalyst may be unsupported or disposed on a solid support (e.g., carbon, silica, or alumina). The hydrosilylation catalyst may be microencapsulated in a thermoplastic resin for increased stability during storage of the silicone composition before curing. When curing is desired, the microencapsulated catalyst (e.g., see U.S. Pat. No. 4,766,176 and U.S. Pat. No. 5,017,654) may be heated about the melting or softening point of the thermoplastic resin, thereby exposing the hydrosilylation catalyst to ingredients (A) and (B). The hydrosilylation catalyst may be a photoactivatable catalyst (e.g., platinum(II) β-diketonate complexes such as platinum(II) bis(2,4-pentanedionate)) for increased stability during storage of the silicone composition before curing. When curing is desired, the photoactivatable catalyst may be exposed to ultraviolet radiation having a wavelength of from 150 to 800 nanometers (nm), thereby activating the catalyst to the hydrosilylation reaction of ingredients (A) and (B).

The catalytically effective amount of the hydrosilylation catalyst is any quantity sufficient to catalyze, increase the rate of hydrosilylation of the diorganosilicon compound and organohydrogensilicon compound. A suitable concentration of the hydrosilylation catalyst in the hydrosilylation curable LSR is from 0.1 to 1000 parts per million (ppm), alternatively from 1 to 500 ppm, alternatively from 3 to 150 ppm, alternatively from 1 to 25 ppm, based on the combined weight of the diorganosilicon compound and the organohydrogensilicon compound.

The hydrosilylation curable silicone composition may have a molar ratio of total silicon-bonded hydrogen atoms to unsaturated carbon-carbon bonds of from 0.05 to 100, alternatively from 0.1 to 100, alternatively from 0.05 to 20, alternatively from 0.5 to 2, alternatively from 1.5 to 5. When ingredients (A) and (B) are different molecules, the hydrosilylation curable silicone composition may have a molar ratio of silicon-bonded hydrogen atoms per molecule of the organohydrogensilicon compound to unsaturated carbon-carbon bonds per molecule of the diorganosilicon compound of from 0.05 to 100, alternatively from 0.1 to 100, alternatively from 0.05 to 20, alternatively from 0.5 to 2, alternatively from 1.5 to 5. A stoichiometric excess of silicon bonded hydrogen atoms to unsaturated carbon-carbon bonds may enhance adhesion between the silicone junction box and a silicone pottant, if any.

In particular applications, it may be desirable for the silicone composition, including the hydrosilylation LSR, to further comprise at least one additional ingredient that is distinct from ingredients (A) to (C). For example, if greater structural strength, fire retardancy, electrical insulation, or any combination thereof is desired, the silicone composition may further comprise at least one filler effective therefor. The at least one filler is distinct from ingredients (A) to (C). The at least one filler may be ingredient (D): a reinforcing effective amount of a reinforcing filler; a flame retarding amount of a fire retarding filler; an electrically insulating amount of an electrical insulating filler; or any combination thereof, wherein a single filler material may have a combination of two or three of the foregoing functions or effects. The filler may be a finely divided solid material. Examples of the reinforcing filler are high surface area fumed and precipitated silicas (e.g., CAB-O-SIL S-17D fumed silica from Cabot Corporation, Boston, Mass., USA) and finely divided zinc oxide, aluminum, aluminum powder, aluminum tri-hydrate, silver, calcium carbonate, quartz (e.g., MIN-U-SIL ground quartz, U.S. Silica Company, Berkeley Springs, W. Va., USA), diatomaceous earths, barium sulfate, iron oxide, titanium dioxide, carbon black, glass spheres, glass fibers, talc, wollastonite, aluminite, calcium sulfate (anhydrite), gypsum, calcium sulfate, magnesium carbonate, clays (e.g., kaolin), aluminum trihydroxide, magnesium hydroxide (brucite), graphite, copper carbonate (e.g., malachite), nickel carbonate (e.g., zarachite), barium carbonate (e.g., witherite), strontium carbonate (e.g., strontianite), aluminum oxide, silicates (e.g., olivine groups, garnet groups, aluminosilicates, ring silicates, chain silicates, and sheet silicates), and any combinations thereof.

The foregoing fillers may be surface treated with fatty acids or fatty acid esters such as stearates; alternatively the foregoing fillers may be organosilanes, organosiloxanes, organosilazanes (e.g., hexaalkyl disilazane), or short chain siloxane diols; alternatively the foregoing fillers may be any combination of at least two thereof. The surface treatment may render the filler hydrophobic; make the fillers easier to handle and less electrically conductive; alternatively enable higher filler loadings in the silicone composition; alternatively any combination thereof, than corresponding non-treated fillers. Surface treated ground silicate minerals may be more easily wetted than untreated silicates. Treated fillers may have improved room temperature mechanical properties. The total amount of the filler(s) in the silicone composition may depend on one or more factors such as type of filler selected and type of surface treatment, if any. The total amount of the filler(s) typically in the silicone composition may be from 10 to 70 wt %, from 20 to 60 wt %, from 40 to 60 wt %, or from 45 to 55 wt %.

Suitable flame retardants may particularly include, for example, carbon black, hydrated aluminum hydroxide, and silicates such as wollastonite, platinum and platinum compounds. Alternatively, the flame retardant may be at least one of halogen based flame-retardants such as decabromodiphenyloxide, octabromordiphenyl oxide, hexabromocyclododecane, decabromobiphenyl oxide, diphenyoxybenzene, ethylene bis-tetrabromophthalmide, pentabromoethyl benzene, pentabromobenzyl acrylate, tribromophenyl maleic imide, tetrabromobisphenyl A, bis-(tribromophenoxy) ethane, bis-(pentabromophenoxy) ethane, polydibomophenylene oxide, tribromophenylallyl ether, bis-dibromopropyl ether, tetrabromophthalic anhydride, dibromoneopentyl glycol, dibromoethyl dibromocyclohexane, pentabromodiphenyl oxide, tribromostyrene, pentabromochlorocyclohexane, tetrabromoxylene, hexabromocyclododecane, brominated polystyrene, tetradecabromodiphenoxybenzene, trifluoropropene, and PVC. Alternatively, the flame retardant may be at least one of phosphorus based flame-retardants such as (2,3-dibromopropyl)-phosphate, phosphorus, cyclic phosphates, triaryl phosphate, bis-melaminium pentate, pentaerythritol bicyclic phosphate, dimethyl methyl phosphate, phosphine oxide diol, triphenyl phosphate, tris-(2-chloroethyl) phosphate, phosphate esters such as tricreyl, trixylenyl, isodecyl diphenyl, ethylhexyl diphenyl, phosphate salts of various amines such as ammonium phosphate, trioctyl, tributyl or tris-butoxyethyl phosphate ester. Other flame retardants may include tetraalkyl lead compounds such as tetraethyl lead, iron pentacarbonyl, manganese methyl cyclopentadienyl tricarbonyl, melamine and derivatives such as melamine salts, guanidine, dicyandiamide, ammonium sulphamate, alumina trihydrate, and magnesium hydroxide alumina trihydrate. The amount of flame retardant can vary depending on factors such as the flame retardant selected and intended use of the silicone junction box. The amount of flame retardant in the silicone composition may depend on the particular flame retardant employed, if any, and typically may range from greater than 0 wt % to 10 wt % based on total weight of the silicone composition.

In particular applications, it may be desirable for the silicone composition, including the hydrosilylation LSR, to further comprise at least one additional ingredient that is distinct from ingredients (A) to (D) and that is ingredient (E): at least one vehicle. Each vehicle independently may function as a solvent, dispersant, or rheology modifier (e.g., plasticizer), which may aid molding or shaping of the curable LSR. Examples of vehicle are an organic solvent (e.g., having a boiling point<120° C.), or a low viscosity polydimethylsiloxane fluid having a kinematic viscosity of from 100 cSt to 1000 cSt (e.g., Dow Corning™ 200 fluid having kinematic viscosity of 1000 cSt) determined according to test method ASTM-D445-11a (Standard Test Method for Kinematic Viscosity of Transparent and Opaque Liquids (and Calculation of Dynamic Viscosity)), e.g., at 25° C. The amount of ingredient (E) can depend on various factors including the type of vehicle selected and the amount and type of other ingredients selected for the silicone composition. However when present, ingredient (E) may range from 0.1 to 20 wt %, alternatively from 1 to 15 wt %, alternatively from 2 wt % to 10 wt % of the composition.

In particular applications, it may be desirable for the silicone composition, including the hydrosilylation LSR, to further comprise at least one additional ingredient that is distinct from ingredients (A) to (E) and that is ingredient (F): at least one acid or base for adjusting pH of the silicone composition. The acid may be a protic acid such as a carboxylic acid (e.g., citric acid or acetic acid) or a salt of dihydrogen phosphate (e.g., ammonium dihydrogenphosphate). The base may be an alkali or alkaline metal carbonate or bicarbonate (e.g., sodium, potassium, magnesium, or calcium (bi)carbonate), or hydroxide (e.g., sodium, potassium, magnesium, or calcium hydroxide).

In particular applications, it may be desirable for the silicone composition, including the hydrosilylation LSR, to further comprise at least one additional ingredient that is distinct from ingredients (A) to (F) and that is ingredient (G): an inhibitor of hydrosilylation reaction. Examples of such inhibitors are acetylenic alcohols, silylated acetylenic compounds, cycloalkenylsiloxanes, ene-yne compounds, triazoles, phosphines, mercaptans, hydrazines, amines, fumarate diesters, and maleate diesters, Examples of the acetylenic alcohols are 1-propyn-3-ol; 1-butyn-3-ol; 2-methyl-3-butyn-2-ol; 3-methyl-1-butyn-3-ol; 3-methyl-1-pentyn-3-ol; 4-ethyl-1-octyn-3-ol; 1-ethynyl-1-cyclohexanol; 3,5-dimethyl-1-hexyn-3-ol; 4-ethyl-1-octyn-3-ol; 1-ethynyl-1-cyclohexanol; 3-phenyl-1-butyn-3-ol; and 2-phenyl-3-butyn-2-ol. E.g., ingredient (G) may be 1-ethynyl-1-cyclohexanol. Examples of cycloalkenylsiloxanes are methylvinylcyclosiloxanes, e.g., 1,3,5,7-tetramethyl-1,3,5,7-tetravinylcyclotetrasiloxane and 1,3,5,7-tetramethyl-1,3,5,7-tetrahexenylcyclotetrasiloxane. Examples of ene-yne compounds are 3-methyl-3-penten-1-yne and 3,5-dimethyl-3-hexen-1-yne. An example of triazoles is benzotriazole. An example of phosphines is triphenylphosphine. Examples of fumarate diesters are dialkyl fumarates, dialkenyl fumarates (e.g., diallyl fumarates), and dialkoxyalkyl fumarates. Examples of maleate diesters are dialklyl maleates and diallyl maleates. Examples of silylated acetylenic compounds are (3-methyl-1-butyn-3-oxy)trimethylsilane, ((1,1-dimethyl-2-propynyl)oxy)trimethylsilane, bis(3-methyl-1-butyn-3-oxy)dimethylsilane, bis(3-methyl-1-butyn-3-oxy)silanemethylvinylsilane, bis((1,1-dimethyl-2-propynyl)oxy)dimethylsilane, methyl(tris(1,1-dimethyl-2-propynyloxy))silane, methyl(tris(3-methyl-1-butyn-3-oxy))silane, (3-methyl-1-butyn-3-oxy)dimethylphenylsilane, (3-methyl-1-butyn-3-oxy)dimethylhexenylsilane, (3-methyl-1-Butyn-3-oxy)triethylsilane, bis(3-methyl-1-butyn-3-oxy)methyltrifluoropropylsilane, (3,5-dimethyl-1-hexyn-3-oxy)trimethylsilane, (3-phenyl-1-butyn-3-oxy)diphenylmethylsilane, (3-phenyl-1-butyn-3-oxy)dimethylphenylsilane, (3-phenyl-1-butyn-3-oxy)dimethylvinylsilane, (3-phenyl-1-butyn-3-oxy)dimethylhexenylsilane, (cyclohexyl-1-ethyn-1-oxy)dimethylhexenylsilane, (cyclohexyl-1-ethyn-1-oxy)dimethylvinylsilane, (cyclohexyl-1-ethyn-1-oxy)diphenylmethylsilane, and (cyclohexyl-1-ethyn-1-oxy)trimethylsilane. E.g., ingredient (G) may be methyl(tris(1,1-dimethyl-2-propynyloxy))silane or ((1,1-dimethyl-2-propynyl)oxy)trimethylsilane. Ingredient (G) may be a combination of any two or more of the foregoing examples, either taken from within a single structural class or from at least two different structural classes.

The silicone composition, including the hydrosilylation LSR, may further comprise at least one of ingredients (H) to (V): (H) pigments, (I) adhesion promoters, (J) corrosion inhibitors, (K) dyes, (L) anti-soiling additives, and combinations thereof. The additional ingredients (D) to (L) are optional, are each independently present in or absent from the composition, and are distinct from one another and from ingredients (A) to (C) and are generally known in the art to be compatible with reaction curing of silicone compositions. There may be overlap between types or functions of ingredients because certain ingredients described herein may have more than one function.

The silicone composition may consist (essentially) of ingredients (A) to (C), which means the composition lacks ingredients (D) to (L). Alternatively, the silicone composition may consist (essentially) of (A) to (D), which means the composition lacks ingredients (E) to (L). Alternatively, the silicone composition may consist (essentially) of (A) to (E), which means the composition lacks ingredients (F) to (L). Alternatively, the silicone composition may consist (essentially) of (A) to (F), which means the composition lacks ingredients (G) to (L). Alternatively, the silicone composition may consist (essentially) of (A) to (G), which means the composition lacks ingredients (H) to (L). Alternatively, the silicone composition may consist (essentially) of (A) to (G) and at least one of ingredients (H) to (L); and lacks any of the other of ingredients (H) to (L).

The silicone composition may be prepared by a method comprising combining the ingredients such as by mixing. The present invention contemplates such a method. The ingredients may be combined in any order, simultaneously, or any combination thereof unless otherwise noted herein. Typically mechanics of the combining comprises contacting and mixing ingredients with equipment suitable for the mixing. The equipment is not specifically restricted and may be, e.g., agitated batch kettles for relatively high flowability (low dynamic viscosity) compositions, a ribbon blender, solution blender, co-kneader, twin-rotor mixer, Banbury-type mixer, or extruder. The method may employ continuous compounding equipment, e.g., extruders such as twin screw extruders (e.g., Baker Perkins sigma blade mixer or high shear Turello mixer), may be used for preparing compositions containing relatively high amounts of particulates. The silicone composition may be prepared in batch, semi-batch, semi-continuous, or continuous process. General methods are known, e.g., US 2009/0291238; US 2008/0300358.

The silicone composition may be prepared as a one part or multiple part composition. The one-part composition may be prepared by combining all ingredients by any convenient means, such as mixing, e.g., as described for the method. All mixing steps or just a final mixing step may be performed under conditions that minimize or avoid curing. The multiple part (e.g., 2 part) composition may be prepared where at least one of ingredients (A) and (B) are stored in one part and ingredient (C) and, optionally the other of ingredients (A) and (B), is stored in a separate part, and the parts are combined (e.g., by mixing) shortly before use of the composition. Typically ingredients (B) and (C) are stored in separate parts when ingredient (C) is catalytically active (not microencapsulated or not inhibited with ingredient (G)). E.g., ingredient (C) may be mixed with all of ingredient (A) in a curing agent part and ingredient (B) may be a base part. Alternatively, ingredient (C) may be mixed with a portion of ingredient (A) in a curing agent part; and ingredient (B) and the remaining portion of ingredient (A) may be mixed together in a base part.

Once prepared the silicone composition may be used immediately or stored for any practical period, e.g., ≧1 hour, alternatively ≧1 day, alternatively ≧1 week, alternatively ≧30 days, alternatively ≧300 days, alternatively ≧2 years before use. The silicone composition may be stored in a container that protects the silicone composition from exposure to curing conditions (e.g., heat). The storage may be at a suitable temperature (e.g., ≦40° C., e.g., 25° C.) and, if desired, under an inert gas atmosphere (e.g., N₂ or Ar gas). When desired, curing of the silicone composition may be initiated by exposing it to the curing conditions to give the cured material.

The silicone junction box may be made by injection molding. For example, a controlled amount of a curing part comprising the hydrosilylation curable liquid silicone rubber and platinum compound catalyst and a controlled amount of a base part containing the organohydrogensilicon compound may be pumped by metering pumps through a static mixer. If desired, controlled amounts of additional ingredients (e.g., ingredients (D) to (L)) may be added to and premixed in the curing part or base part, as the case may warrant, before the curing and base parts are pumped through the static mixer. For example, controlled amounts of ingredients (D) and (E), and optionally ingredient (F), may be added to and premixed in the curing part and a controlled amount of ingredient (G), and optionally ingredient (E), may be added to and premixed in the base part before the curing and base parts enter the static mixer. All the ingredients together form a homogeneous mixture in the static mixer. The mixture exits the mixer and is injected into a suitably shaped mold. The mold typically is made of a material that may be conformed to define a cavity having a shape or contour that is effective for producing a desired configuration of the silicone junction box. The mold, at least the portion defining the cavity, withstands the curing conditions. Typically the mold material may be a metal, e.g., steel or aluminum. There may be one mold that defines a cavity suitably dimensioned for configuring the silicone base member, alternatively one mold configured for making the silicone junction box where the cover member is a cured LSR and the silicone cover and base members are part of a same molded silicone piece. Alternatively there may be two molds, one for making the silicone cover member and one for making the silicone base member, which is later connected to the silicone cover member. The mold cavity may be heated. The surface of the mold defining the cavity may be coated before each use with a release agent, e.g., a silicon-based release agent. Temperatures of the mold and ingredients entering the mold may be the same or different. Once in the mold cavity, the mixture undergoes at least partial curing (vulcanization) and, typically cooling. The resulting silicone junction box comprising a molded LSR silicone base member and, optionally a molded LSR silicone cover member. The released injection-molded, silicone junction box may be an injection-molded, photovoltaic use-type silicone junction box.

The silicone junction box may be adapted to any configuration suitable for housing the electrical connection(s). Many different junction box configurations are well known in the art and are contemplated by this invention. As a general illustration, the silicone junction box may comprise a single piece, or multiple pieces (e.g., 2 or 3 pieces). The single piece configuration of the silicone junction box has at least one aperture through which electrical connectors (e.g., interconnects, fuses, transistors, capacitors, and switches) may be disposed therein and cables (e.g., wires or other electrical conduits) from other electrical devices (e.g., power grid, lights, inverters, batteries, solar panels, and the subassembly of the photovoltaic panel) may be extended therethrough and in electrical connection to the electrical connectors therein. The single piece configuration of the silicone junction box includes a unitary configuration comprising the silicone base member and a flap-like cover member. The silicone base member may be configured as a plate or box and may define an aperture for extending at least one cable from an electrical device therethrough. The silicone base member may have at least one peripheral edge, including a flexible peripheral edge that functions as a hinge and is connected to the flap-like cover member. The flap-like cover member is movable with the flexible peripheral edge between a closed position and an open position. When the flap-like cover member is in the closed position the flap-like cover member may be operatively connected to the silicone base member by a connecting means (see below). When the flap-like cover member is in the open position the interior of the silicone junction box is exposed for making the aforementioned electrical connections and, optionally, for allowing coating of the latter with a silicone pottant. Individual pieces of the multiple piece configuration of the silicone junction box independently may or may not have apertures. Overall the multiple piece silicone junction box defines at least one aperture through which cables (e.g., wires or other electricity conducting conduit) may be extended, e.g., the aperture may be defined by a cut-out portion in the silicone base member, or two complimentary-fitting cut-out portions in the silicone base and silicone cover members. An example of the cut-out portion is a U-shaped portion. An example of the multiple piece configuration comprises a silicone base member defining an aperture and a silicone cover member disposed for operative connection to the silicone base member. The silicone cover member may be configuration such as a plate, or a box having sides (or a single side if round, oval or otherwise lacks defined corners). In any configuration, the operative connection(s) independently may comprise same or different connecting means. Any connecting means may be used to operatively attach the cover member to the silicone base member such as, e.g., an adhesive (e.g., a silicone adhesive), braze joint, buckle, button, cement, clamp, clasp, clip such as a spring clip, crimping, friction fit, hook-and-loop strips (e.g., VELCRO), magnets, pin, pottant (e.g., silicone pottant), pressure fit, rivet, screw-threaded fastener (e.g., screw and bolt/nut), sealant (e.g., a silicone sealant), snap fit, solder, staple, tape, vacuum, wrap (e.g., rubber band or plastic wrap or exterior coating of sealant), weld, or zipper.

As a general illustration for the photovoltaic use-type silicone junction box comprising the silicone base member made of silicone, the electrical connector disposed within the silicone junction box may be disposed in the electrical connection to the subassembly of the photovoltaic panel, and thus in electrical connection to the photovoltaic cells, by any suitable means. Examples of such means for electrically connecting the photovoltaic cells to the electrical connector are electrical cable, electrical wire, solder, tabbing, and direct contact between, e.g., a busbar of one of the cells and a conducting portion of the electrical connector. The photovoltaic panel assembly and photovoltaic system comprises such means. The subassembly may be electrically connected within the photovoltaic use-type silicone junction box to a cable from an inverter, storage battery, electrical grid, or any combination thereof. The photovoltaic panel, photovoltaic use-type silicone junction box, and inverter together comprise a typical photovoltaic system, which more typically contains a plurality of such panels and photovoltaic use-type silicone junction boxes. The subassembly of each photovoltaic panel typically comprises one or more buss wires protruding therefrom, typically from an opening in a back side of the photovoltaic panel. The buss wires are for electrically connecting the solar cells of the subassembly to the electrical connectors in the photovoltaic use-type silicone junction box. The photovoltaic use-type silicone junction box may be of a 1-, 2-, 3-, or more than 3-piece configuration as described in general terms previously. For example, a two-piece photovoltaic use-type silicone junction box configuration may comprise the silicone base member and a silicone cover member, which may be operatively attached to the silicone base member by any suitable connection means, e.g., hingably connected to the silicone base member with at least one hinge (e.g., at least one barrel hinge or a continuous hinge). The silicone base member defines an aperture and is adhered to a back side of a photovoltaic panel such that the aperture thereof is disposed over the opening in the back side of the panel from which the buss wires protrude. The buss wires may then be electrically connected (e.g., by soldering, mechanical (e.g., twisting leads of the wires together), or other suitable means), to electrical connectors, which are disposed in the photovoltaic use-type silicone junction box. The electrical connectors may be in turn electrically connected to a cable or wires entering the box from the inverter, electricity grid, storage battery, or any combination thereof. The electrical connectors may be a separate component from or integral with the photovoltaic use-type silicone junction box. After all the electrical connections are made, any additional components or (electrical) connections may be made in or to the box, and then the silicone cover member may be operatively connected to the silicone base member so as to enclose the photovoltaic use-type silicone junction box. Optionally, a silicone pottant may be added onto and around the electrical connections before or after the silicone cover member is attached to the silicone base member. The silicone pottant functions to coat and protect the electrical connections from the abusive environments such as heat, cold, weather elements, dust (e.g., sand or dirt particles), physical impact or vibration, or other abusive elements, as the case may be. The amount of silicone pottant used may be from a minimum quantity sufficient for coating and protecting the electrical connections up to and including a maximum quantity sufficient to fill the photovoltaic use-type silicone junction box and seal the aperture in the silicone base member around the buss wires and seal (close up) any other apertures in the photovoltaic use-type silicone junction box. The silicone pottant may also function as an adhesive for inhibiting the cables that extend into the photovoltaic use-type silicone junction box from being inadvertently loosened or pulled away from the electrical connectors, or pulled out of the photovoltaic use-type silicone junction box. The photovoltaic use-type silicone junction box may be operatively connected to the back side of the photovoltaic panel with a silicone adhesive, which may be in sealing operative contact with the back side of the photovoltaic panel and an exterior surface of the silicone base member or the silicone cover member.

The invention is further illustrated by, and each embodiment of the invention may be any combinations of features and limitations of, the non-limiting examples that follow. Some specific configurations suitable for the silicone junction box may be adopted from configurations of known non-silicone junction boxes such as the non-silicone photovoltaic use-type junction boxes found in U.S. Pat. No. 7,833,033 B2; U.S. Pat. No. 7,134,883 B2; U.S. Pat. No. 7,097,516 B2; U.S. Pat. No. 6,582,249 B1; US 2011/0168228 A1; US 2011/0147076 A1; and US 2005/0161080 A1.

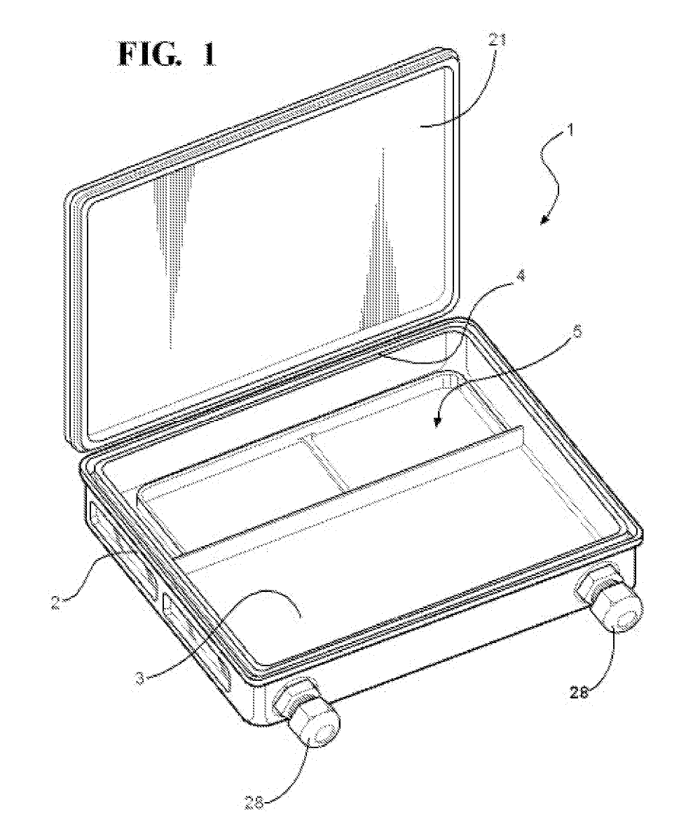

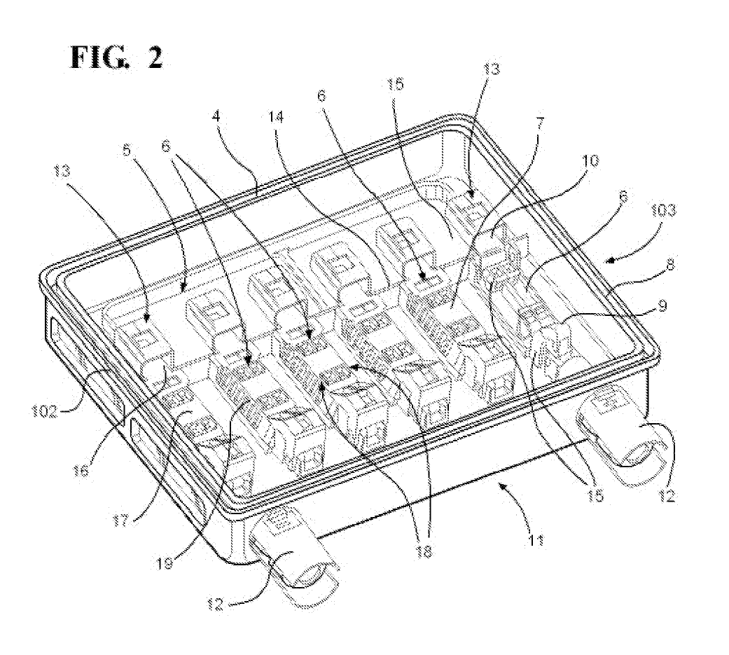

For example, the silicone junction box may be the photovoltaic use-type silicone junction box of present FIG. 1. FIG. 1 is the perspective view of an embodiment of the silicone junction box with the cover member in an open position. The silicone junction box may be used as the photovoltaic use-type silicone junction box. In FIG. 1, silicone junction box 1 comprises silicone base member 3 and cover member 21 in operative connection thereto. Silicone base member 3 has a peripheral edge 2. An opening 5 is formed in silicone base member 3 adjacent to a back edge region 4. Silicone junction box 1 comprises cable openings 28 via which an electric cable (not shown) can be connected to conductor rails 6 (see FIG. 2). Cover member 21 may be moved between the shown open position and a closed position (not shown) where cover member 21 is in sealing operative contact with peripheral edge 2 of silicone junction box 1.

FIG. 2 is a perspective view of another embodiment of the silicone base member (an embodiment of the silicone junction box that is shown without the cover member) and further comprising electrical connectors disposed therein. In FIG. 2, six conductor rails 6 are arranged on silicone base member 103 having peripheral edge 102. Two to six conductor rails 6 may be arranged depending on the construction. A respective rail cover 7 is provided on five conductor rails 6. One conductor rail 6, arranged next to a right-hand side wall 8, is shown for illustration without the rail cover 7. One conductor rail 6 comprises a first contact element 9 opposite a second contact element 10. The first contact elements 9 of the conductor rails 6 are associated with a connection side 11 of silicone base member 103 (another embodiment of the silicone base member). The connection side 11 may optionally define apertures or incorporate electrical connectors therein (not shown). The second contact elements 10 of the conductor rails 6 are associated with the opening 5. The conductor rails 6 are arranged parallel and side by side. Contact terminals 12 are arranged on the connection side 11 of silicone base member 103. The contact terminals 12 are either constructed as contact plugs or as contact sockets. The two contact terminals 12 are each electrically connected to the first contact elements 9 of the outer conductor rails 6. The second contact elements 10 are surrounded by a contact cage 13. The second contact elements 10 are associated with openings of a wall 14 used for feeding electric lines from the photovoltaic panel. The wall 14 extends adjacent to the opening 5 over the entire width of the silicone base member 103. Holding devices 15, into which the conductor rails 6 are inserted, are provided on the silicone base member 103. The holding devices 15 are also used to hold the rail covers 7 and the contact cages 13. The contact cages 13 have insertion openings 16 facing the conductor rails 6 into which the second contact elements 10 are positioned in the contact cage 13. Each rail cover 7 has an upper side 17 which is substantially rectangular in construction and is arranged along the longitudinal direction of the conductor rail 6. The upper side 17 has side walls 18 arranged to be angled downwards at the side and inserted into the holding devices 15. Contact openings 19 are located on the upper side 17. The contact openings 19 are arranged over contact regions of the conductor rails 6 and can therefore be contacted through the rail cover 7. The upper side 17 is substantially constructed as a flat face. The upper sides of the rail covers 7 are preferably arranged on approximately the same plane. The upper sides 17 therefore form a relatively large overall bearing surface for a printed circuit board 20 (see FIG. 3).

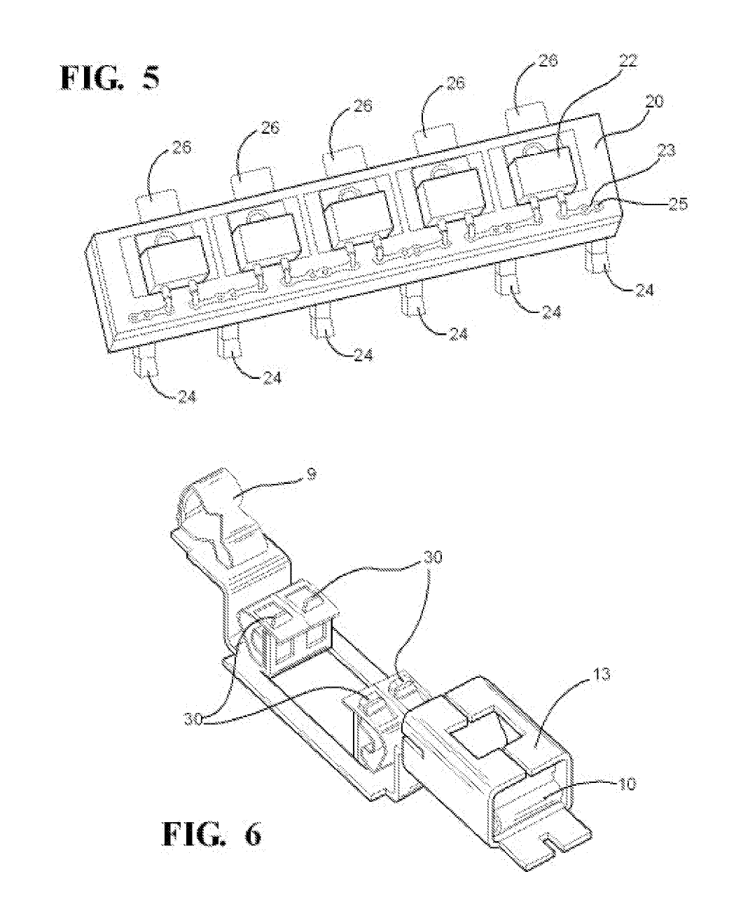

FIG. 3 is a perspective view of the embodiment of the silicone junction box 1 of FIG. 1 comprising silicone base member 3 and cover member 21 and further comprising additional electrical connectors and showing additional features comprising a printed circuit board 20 that is fastened to the silicone base member 3. The printed circuit board 20 comprises components 22 which are assembled on the printed circuit board 20 and connected by electrical terminals (not shown) to traces 23 of the printed circuit board 20. The traces 23 produce an electrical connection between the components 22 and terminal pins 24 (see FIG. 5) which are arranged on the lower side of the printed circuit board 20 and are thus not visible in FIG. 2. The terminal pins 24 (see FIG. 5) are guided through the contact openings 19 in the contact regions of the conductor rails 6 and therefore produce an electrical connection between the conductor rails 6 and the components 22. The components 22 may be diodes, which depending on the embodiment and connection of the conductor rails, are connected to positive or negative lines of a solar panel and connect the conductor rails 6 to one another in a desired electrical function. The three right-hand conductor rails 6 are connected in this example to electric lines of the solar panel which carry a positive voltage. The three left-hand conductor rails 6 are connected in this embodiment to electric lines of the solar panel which carry a negative voltage. The terminal pins 24 (see FIG. 5) are arranged on the lower side of the printed circuit board and are electrically connected to the traces 23 via plated through holes 25. In this embodiment the printed circuit board 20 has terminals 26 which are led out of the printed circuit board 20 at a longitudinal side thereof and are inserted in insertion openings 16 of the contact cages 13. The width of the terminals 26 is adapted to the width of the insertion openings 16 such that a spring loaded connection is produced between the printed circuit board 20 and the contact cages 13. In addition, the printed circuit board 20 is located on the upper sides 17 of the covers 7. Components that can be surface mounted may be used as the components 22. In contrast to silicone base member 103 in FIG. 2, silicone base member 3 of FIGS. 1 and 3 comprises cable openings 28 via which the electric cable can be connected to the conductor rails 6. Instead of the terminal pins 24, (see FIG. 5) electric lines may also be provided.

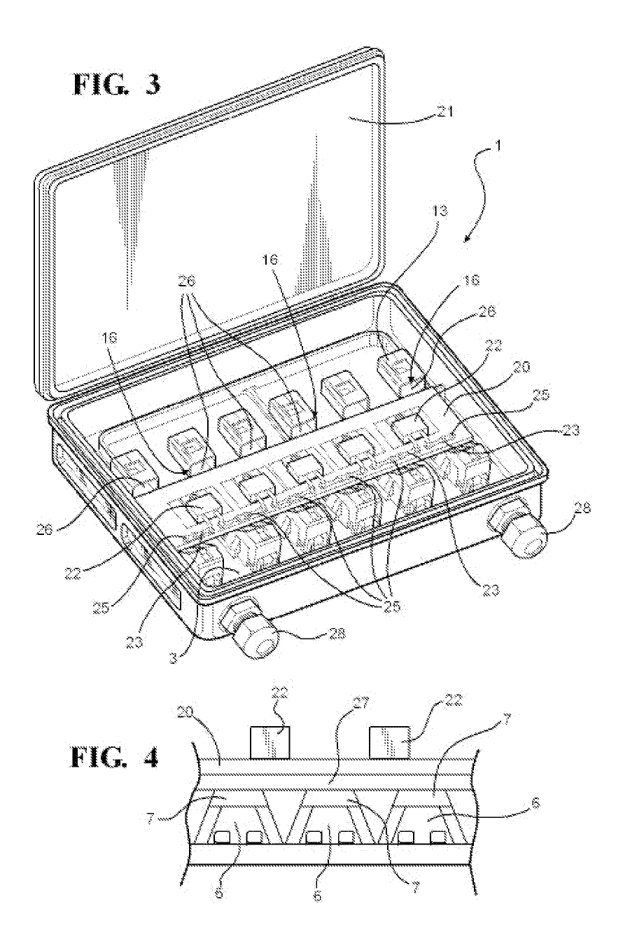

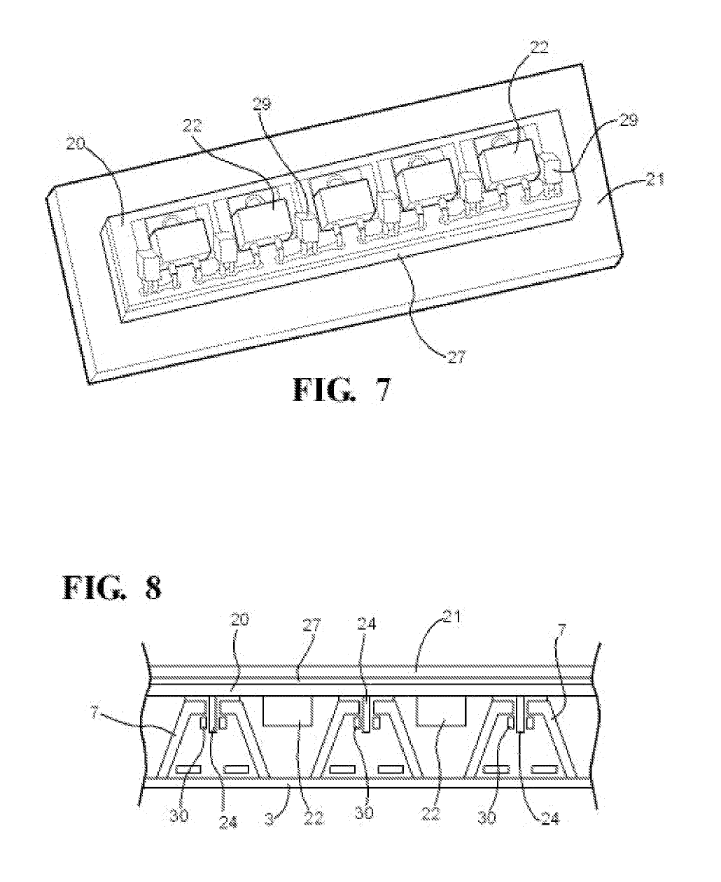

FIG. 4 is a cross-sectional view through the printed circuit board 6 and the printed circuit board 20. A silicone adhesive layer 27 (see also FIGS. 7 and 8) in the form of a continuous silicone adhesive layer is formed between the printed circuit board 20 and the rail covers 7. The printed circuit board 20 thus adheres to the rail covers 7 which are in turn rigidly connected to the silicone junction box 1 via the holding devices 15 (see FIG. 2). The silicone adhesive layer 27 is preferably arranged only in the region of the upper sides 17 (see FIG. 2). The silicone adhesive layer 27 can be constructed as a heat conducting layer, depending on the embodiment.

FIG. 5 is a perspective view of an embodiment of the printed circuit board 20 of FIGS. 2 and 4. The silicone adhesive layer 27 (see FIGS. 4, 7 and 8) is provided on the lower side of the printed circuit board 20 on which the terminal pins 24 are also arranged with which an electrical connection is made between the components 22 of the printed circuit board 20 and the conductor rails 6 (see FIG. 2). In the process the terminal pins 24 are inserted through the contact openings 19 (see FIG. 2) of the rail covers 7 (see FIGS. 2 and 4) in contact regions 30 (see FIGS. 6 and 8) of the conductor rails 6 (see FIG. 2).

FIG. 6 is a perspective view of a conductor rail 6 comprising a first and a second contact element 9, 10. The conductor rail 6 has four contact regions 30 which are arranged between the first and the second contact element 9, 10. Two respective contact regions 30 are associated with the first or second contact element 9, 10. A contact region 30 is illustrated in the embodiment shown by a spring clip.

FIG. 7 is a perspective view showing an alternate embodiment wherein a printed circuit board 20 is fastened to the cover member 21. FIG. 7 shows detail of a further embodiment of a printed circuit board 20 in which the components 22 are arranged on the lower side of the printed circuit board 20, like the pin contacts 29. A silicone adhesive layer 27 with which the printed circuit board 20 is glued to the cover member 21 in the assembled state, is constructed on the upper side of the printed circuit board 20 in this embodiment.

FIG. 8 is a cross-sectional view through the silicone junction box 1 (see FIGS. 1 and 3) and the printed circuit board 20 of FIG. 7 assembled in the connecting box. In this embodiment the components 22 are arranged between the rail covers 7. The pin contacts 29 are guided through the contact openings 19 of the rail covers 7 into the contact regions 30. The silicone adhesive layer 27, which is glued to the cover member 21, is formed on the upper side of the printed circuit board 20.

Alternatively, for example, the photovoltaic use-type silicone junction box as described herein may be configured by adopting the non-silicone photovoltaic use-type junction box configuration by making out of the present silicone composition one of the following non-silicone junction box component assemblies (a) to (f): (a) Plate member 201, base member 401, and frame member 519, all of U.S. Pat. No. 7,833,033 B2; (b) Alternatively, inter alia, base board 2, circular side wall 3, and removable lid 16, or based on housing wall 24, peripheral side wall 37, and lid 38, all of U.S. Pat. No. 7,097,516 B2; (c) Alternatively, housing 2, base 3, lateral walls 4, and diaphragm cover 11, all of U.S. Pat. No. 6,582,249 B1; (d) Alternatively, base portion 18 and cover 20, all of US 2011/0168228 A1; (e) Alternatively, housing body 300 and housing cover 400, all of US 2011/0147076 A1; (f) Alternatively, housing 1 comprising side walls 2, cover 3, and bottom 4, all of US 2005/0161080 A1.

“May” confers a choice, not an imperative. In a combination of a first selection from a genus of (a), (b), or (c) and a second selection from the subgenus (a) wherein the first and second selections are different, the first selection may also be from the subgenus (a) as long as it is a different selection than the second selection. “Optionally” means is absent, alternatively is present. “Operative contact” comprises functionally effective (indirect), alternatively physically touching (direct). All “wt %” (weight percent) are, unless otherwise noted, based on total weight of all ingredients used to make the composition, which adds up to 100 wt %. “Curable amount” is a quantity sufficient for producing the cured material. All viscosities are conducted at 25° C. unless otherwise noted.

In some embodiments the invention may be any one of Aspects 1 to 12. Aspect 1 is a silicone junction box comprising a silicone base member comprising a silicone composition for housing an electrical connection and a cover member in sealing operative contact with the silicone base member.

Aspect 2 is the silicone junction box of aspect 1, wherein the cover member is a silicone cover member comprising a silicone composition that is the same or different than the silicone composition of the silicone base member.

Aspect 3 is a silicone junction box of aspect 1 or 2 that is a photovoltaic use-type silicone junction box and the electrical connection is a photovoltaic use-type electrical connection.

Aspect 4 is a silicone junction box of any one of aspects 1-3, wherein the silicone composition is an at least partially cured, hydrosilylation curable silicone composition.

Aspect 5 is a silicone junction box of aspect 4, wherein the hydrosilylation curable silicone composition, before the at least partial curing, comprises ingredients (A) to (C): (A) at least one diorganosilicon compound having an average of at least two unsaturated carbon-carbon bonds per molecule; (B) an organohydrogensilicon compound having an average of at least three Si—H moieties per molecule; and (C) a catalytically effective amount of a hydrosilylation catalyst.

Aspect 6 is a silicone junction box of aspect 4 or 5, wherein the hydrosilylation curable silicone composition, before the at least partial curing, further comprises ingredient (D): a reinforcing effective amount of a reinforcing filler; a flame retarding amount of a fire retarding filler; an electrically insulating amount of an electrical insulating filler; or any combination thereof.

Aspect 7 is a silicone junction box of any one of aspects 4 to 6, wherein the hydrosilylation curable silicone composition, before the at least partial curing, further comprises at least one of ingredients (E) to (G): ingredient (E): at least one vehicle; (F) at least one acid or base for adjusting pH of the silicone composition; and ingredient (G): an inhibitor of hydrosilylation reaction.

Aspect 8 is a photovoltaic panel assembly comprising components (a) to (c): (a) a subassembly of electrically connected photovoltaic cells; (b) a silicone junction box comprising a silicone base member comprising a silicone composition for housing an electrical connection and a cover member in sealing operative contact with the silicone base member; and (c) an electrical connector disposed within the silicone junction box and in electrical connection to the subassembly.

Aspect 9 is a photovoltaic panel assembly of aspect 8, wherein the cover member is a silicone cover member comprising a silicone composition that is the same or different than the silicone composition of the silicone base member.

Aspect 10 is a photovoltaic system comprising components (a) to (d): (a) a subassembly of electrically connected photovoltaic cells; (b) a silicone junction box comprising a silicone base member comprising a silicone composition for housing an electrical connection and a cover member in sealing operative contact with the silicone base member; (c) an electrical connector disposed within the silicone junction box and in electrical connection to the subassembly; and (d) an electric cable extending into the silicone junction box and in sequential electrical connection to the electrical connector and subassembly.

Aspect 11 is a photovoltaic system of aspect 10, wherein the cover member is a silicone cover member comprising a silicone composition that is the same or different than the silicone composition of the silicone base member.

Aspect 12 is any one of aspects 1, 2 and 8 to 11, wherein the silicone junction box is a photovoltaic use-type silicone junction box that is characterizable using UL 1703 and UL 746C by an Outdoor use rating of f2 or better; a Flammability rating of 5VA or better; a Hot Wire Ignition rating of ≦4; a High-current Arc Ignition rating of ≦3; a Comparative tracking index rating of ≦2; and a Relative Thermal Index rating of ≧90 degrees Celsius. In some embodiments the invention may be as hereupon claimed.

What is claimed is:

1. A silicone junction box comprising a silicone base member comprising a silicone composition for housing an electrical connection and a cover member in sealing operative contact with the silicone base member.

2. The silicone junction box of claim 1, wherein the cover member is a silicone cover member comprising a silicone composition that is the same or different than the silicone composition of the silicone base member.

3. The silicone junction box of claim 1 that is a photovoltaic use-type silicone junction box that is characterizable using UL 1703 and UL 746C by an Outdoor use rating of f2 or better; a Flammability rating of 5VA or better; a Hot Wire Ignition rating of ≦4; a High-current Arc Ignition rating of ≦3; a Comparative tracking index rating of ≦2; and a Relative Thermal Index rating of ≧90 degrees Celsius.

4. The silicone junction box of claim 1, wherein the silicone composition is an at least partially cured, hydrosilylation curable silicone composition.

5. The silicone junction box of claim 4, wherein the hydrosilylation curable silicone composition, before the at least partial curing, comprises ingredients (A) to (C): (A) at least one diorganosilicon compound having an average of at least two unsaturated carbon-carbon bonds per molecule; (B) an organohydrogensilicon compound having an average of at least three Si—H moieties per molecule; and (C) a catalytically effective amount of a hydrosilylation catalyst.

6. The silicone junction box of claim 5, wherein the hydrosilylation curable silicone composition, before the at least partial curing, further comprises ingredient (D): a reinforcing effective amount of a reinforcing filler; a flame retarding amount of a fire retarding filler; an electrically insulating amount of an electrical insulating filler; or any combination thereof.

7. The silicone junction box of 6, wherein the hydrosilylation curable silicone composition, before the at least partial curing, further comprises at least one of ingredients (E) to (G): ingredient (E): at least one vehicle; (F) at least one acid or base for adjusting pH of the silicone composition; and ingredient (G): an inhibitor of hydrosilylation reaction.

8. A photovoltaic panel assembly comprising components (a) to (c): (a) a subassembly of electrically connected photovoltaic cells; (b) a photovoltaic use-type silicone junction box comprising a silicone base member comprising a silicone composition for housing an electrical connection and a cover member in sealing operative contact with the silicone base member; and (c) an electrical connector disposed within the silicone junction box and in electrical connection to the subassembly.

9. The photovoltaic panel assembly of claim 8, wherein the cover member is a silicone cover member comprising a silicone composition that is the same or different than the silicone composition of the silicone base member.

10. The photovoltaic panel assembly of claim 8 wherein the photovoltaic use-type silicone junction box is characterizable using UL 1703 and UL 746C by an Outdoor use rating of f2 or better; a Flammability rating of 5VA or better; a Hot Wire Ignition rating of ≦4; a High-current Arc Ignition rating of ≦3; a Comparative tracking index rating of ≦2; and a Relative Thermal Index rating of ≧90 degrees Celsius.

11. A photovoltaic system comprising components (a) to (d): (a) a subassembly of electrically connected photovoltaic cells; (b) a photovoltaic use-type silicone junction box comprising a silicone base member comprising a silicone composition for housing an electrical connection and a cover member in sealing operative contact with the silicone base member; (c) an electrical connector disposed within the silicone junction box and in electrical connection to the subassembly; and (d) an electric cable extending into the silicone junction box and in sequential electrical connection to the electrical connector and subassembly.

12. The photovoltaic system of claim 11, wherein the cover member is a silicone cover member comprising a silicone composition that is the same or different than the silicone composition of the silicone base member.

13. The photovoltaic system of claim 11 wherein the photovoltaic use-type silicone junction box is characterizable using UL 1703 and UL 746C by an Outdoor use rating of f2 or better; a Flammability rating of 5VA or better; a Hot Wire Ignition rating of ≦4; a High-current Arc Ignition rating of ≦3; a Comparative tracking index rating of ≦2; and a Relative Thermal Index rating of ≧90 degrees Celsius.
